(19) United States
(12) Patent Application Publication
(10) Pub. No.: US 2020/0053483 A1
(43) Pub. Date: Feb. 13, 2020

(54) SENSOR DEVICES AND METHODS FOR MANUFACTURING THE SAME

(71) Applicant: Infineon Technologies AG, Neubiberg (DE)

(72) Inventor: Horst Theuss, Wenzenbach (DE)

(73) Assignee: Infineon Technologies AG, Neubiberg (DE)

(21) Appl. No.: 16/036,172

(22) Filed: Jul. 16, 2018

(30) Foreign Application Priority Data
Jul. 25, 2017 (DE) 10 2017 212 748.1

(51) Int. Cl. H04R 19/04; B81B 7/00; B81C 1/00; H04R 31/00; H04R 1/04; H04R 19/00

(52) U.S. Cl. CPC H04R 19/04; B81B 7/0061; B81B 7/0064; B81C 1/00309; H04R 2201/003; H04R 1/04; H04R 19/005; B81B 2201/0257; B81B 2207/098; H04R 31/003

(57) ABSTRACT

A sensor device including a leadframe is disclosed. A sensor chip is arranged on the leadframe, an encapsulation material is arranged on a main surface and a side surface of the sensor chip, and a signal port arranged at a side surface of the sensor device. The side surface of the sensor device extends between opposing main surfaces of the sensor device, wherein one of the main surfaces is a mounting surface of the sensor device. A channel extends from the signal port to a sensing structure of the sensor chip.

### CROSS-REFERENCE TO RELATED APPLICATION

This Utility patent application claims priority to German Patent Application No. 10 2017 212 748.1, filed Jul. 25, 2017, which is incorporated herein by reference.

### TECHNICAL FIELD

The present disclosure relates in general to semiconductor technology. More particular, the disclosure relates to sensor devices and methods for manufacturing the same.

### BACKGROUND

Sensor devices may include MEMS (Micro-Electro-Mechanical System) semiconductor chips with movable structures. For the purpose of sensing physical signals the movable structures may be accessible via signal ports arranged on the top or bottom surfaces of the sensor devices. An encapsulation or packaging of such sensor devices may require complicated processes resulting in increased manufacturing costs. Manufacturers of sensor devices are constantly striving to improve their products and the methods for manufacturing the same. It may thus be desirable to provide additional layout aspects for sensor devices and associated manufacturing methods that provide more flexibility in the design of the devices and at the same time reduce the manufacturing costs.

### SUMMARY

Various aspects pertain to a sensor device, comprising: a chip carrier; a sensor chip arranged on the chip carrier; an encapsulation material arranged on a main surface and a side surface of the sensor chip; a signal port arranged at a side surface of the sensor device, wherein the side surface of the sensor device extends between opposing main surfaces of the sensor device, wherein one of the main surfaces is a mounting surface of the sensor device; and a channel extending from the signal port to a sensing structure of the sensor chip.

Various aspects pertain to a sensor device, comprising: a chip carrier; a sensor chip arranged on the chip carrier; an encapsulation structure encapsulating the sensor chip; a signal port arranged at a side surface of the sensor device, wherein the side surface of the sensor device extends between opposing main surfaces of the sensor device, one of the main surfaces being a mounting surface of the sensor device, wherein the signal port comprises a hole in the chip carrier; and a channel extending from the hole in the chip carrier to a sensing structure of the sensor chip.

Various aspects pertain to a method for manufacturing a sensor device, the method comprising: arranging multiple sensor chips on a carrier; encapsulating the sensor chips by an encapsulation structure; and separating the encapsulated sensor chips into multiple sensor devices, wherein a signal port arranged at a side surface of each sensor device is produced by the separation process.

### BRIEF DESCRIPTION OF THE DRAWINGS

The accompanying drawings are included to provide a further understanding of aspects and are incorporated in and constitute a part of this specification. The drawings illustrate aspects and together with the description serve to explain principles of aspects. Other aspects and many of the intended advantages of aspects will be readily appreciated as they become better understood by reference to the following detailed description. The elements of the drawings are not necessarily to scale relative to each other. Like reference signs may designate corresponding similar parts.

FIG. 1 schematically illustrates a cross-sectional side view of a sensor device 100 in accordance with the disclosure. The sensor device 100 includes a signal port arranged at a side surface of the sensor device 100. An encapsulation material is arranged on a main surface and a side surface of the sensor chip

FIG. 2 schematically illustrates a cross-sectional side view of a sensor device 200 in accordance with the disclosure. The sensor device 200 includes a signal port arranged at a side surface of the sensor device 200. The signal port includes a hole in a carrier of the sensor device 200.

FIG. 3 includes FIGS. 3A to 3C schematically illustrating a cross-sectional side view of a method for manufacturing a sensor device 300 in accordance with the disclosure. The manufactured sensor device 300 may be similar to the sensor devices of FIGS. 1 and 2.

FIG. 4 includes FIGS. 4A, 4B.1, 4B.2, 4C, 4D, 4E.1, 4E.2, and 4E.3 schematically illustrating a method for manufacturing a sensor device 400 in accordance with the disclosure. The manufactured sensor device 400 may be seen as a more detailed implementation of the sensor devices 100 and 200 of FIGS. 1 and 2. In addition, the illustrated method may be seen as a more detailed implementation of the method of FIG. 3.

FIG. 5 schematically illustrates a perspective view of a chip carrier 500. The chip carrier 500 may be used in the method of FIG. 4. In particular, the chip carrier 500 may replace the chip carrier of FIG. 4A.

FIG. 6 schematically illustrates a perspective view of a chip carrier 600. The chip carrier 600 may be used in the method of FIG. 4. In particular, the chip carrier 600 may replace the chip carrier of FIG. 4A.

FIG. 7 schematically illustrates a perspective view of a chip carrier 700. The chip carrier 700 may be used in the method of FIG. 4. In particular, the chip carrier 700 may replace the chip carrier of FIG. 4A.

FIG. 8 schematically illustrates a top view of an act of encapsulating multiple sensor chips arranged over chip carriers. The illustrated act may be used in the method of FIG. 4. In particular, the act may replace the act of FIG. 4D.

FIG. 9 schematically illustrates a cross-sectional side view of a sensor device 900 in accordance with the disclosure. The sensor device 900 may be manufactured based on the method of FIG. 4. In addition, the sensor device 900 may be seen as more detailed implementation of the sensor devices 100 and 200 of FIGS. 1 and 2.

FIG. 10 schematically illustrates a cross-sectional side view of a sensor device 1000 in accordance with the disclosure. The sensor device 1000 may be manufactured based on the method of FIG. 4. In addition, the sensor device 1000 may be seen as more detailed implementation of the sensor devices 100 and 200 of FIGS. 1 and 2.

FIG. 11 schematically illustrates a cross-sectional side view of a sensor device 1100 in accordance with the disclosure. The sensor device 1100 may be manufactured based on the method of FIG. 4. In addition, the sensor device 1100 may be seen as more detailed implementation of the sensor devices 100 and 200 of FIGS. 1 and 2.

FIG. 12 schematically illustrates a cross-sectional side view of a sensor device 1200 in accordance with the disclosure. The sensor device 1200 may be manufactured based on the method of FIG. 4. In addition, the sensor device 1200 may be seen as more detailed implementation of the sensor devices 100 and 200 of FIGS. 1 and 2.

FIG. 13 includes FIGS. 13A to 13E schematically illustrating a cross-sectional side view of a method for manufacturing a sensor device 1300 in accordance with the disclosure. The manufactured sensor device 1300 may be seen as a more detailed implementation of the sensor devices 100 and 200 of FIGS. 1 and 2. In addition, the illustrated method may be seen as a more detailed implementation of the method of FIG. 3.

FIG. 14 schematically illustrates a cross-sectional side view of a sensor device 1400 in accordance with the disclosure. The sensor device 1400 may be manufactured based on the method of FIG. 13. In addition, the sensor device 1400 may be seen as more detailed implementation of the sensor devices 100 and 200 of FIGS. 1 and 2.

FIG. 15 schematically illustrates a cross-sectional side view of a sensor device 1500 in accordance with the disclosure. The sensor device 1500 may be manufactured based on the method of FIG. 13. In addition, the sensor device 1500 may be seen as more detailed implementation of the sensor devices 100 and 200 of FIGS. 1 and 2.

FIG. 16 includes FIGS. 16A and 16B. FIG. 16A schematically illustrates a cross-sectional side view of a sensor device 1600 in accordance with the disclosure. The sensor device 1600 may be manufactured based on the method of FIG. 13. In addition, the sensor device 1600 may be seen as more detailed implementation of the sensor devices 100 and 200 of FIGS. 1 and 2. FIG. 16B illustrates a perspective bottom view of a sensor chip included in the sensor device 1600. The sensor chip may include a recess that may form a channel in the sensor device 1600.

FIG. 17 includes FIGS. 17A and 17B. FIG. 17A schematically illustrates a cross-sectional side view of a sensor device 1700 in accordance with the disclosure. The sensor device 1700 may be manufactured based on the method of FIG. 13. In addition, the sensor device 1700 may be seen as more detailed implementation of the sensor devices 100 and 200 of FIGS. 1 and 2. FIG. 17B illustrates a perspective top view of a sensor chip and a frame structure arranged around a sensing structure of the sensor chip. The frame structure may form a channel in the sensor device 1700.

FIG. 18 includes FIGS. 18A and 18B. FIG. 18A schematically illustrates a cross-sectional side view of a sensor device 1800 in accordance with the disclosure. The sensor device 1800 may be manufactured based on the method of FIG. 13. In addition, the sensor device 1800 may be seen as more detailed implementation of the sensor devices 100 and 200 of FIGS. 1 and 2. FIG. 18B illustrates a perspective bottom view of a lid arranged over a sensing structure of a sensor chip. The lid may form a channel in the sensor device 1800.

FIG. 19 schematically illustrates a cross-sectional side view of an electronic device 1900, for example a smartphone. The electronic device 1900 includes a sensor device in accordance with the disclosure.

FIG. 20 schematically illustrates a cross-sectional side view of an electronic device 2000, for example a smartphone. The electronic device 2000 includes a sensor device in accordance with the disclosure.

### DETAILED DESCRIPTION

In the following detailed description, reference is made to the accompanying drawings, in which are shown by way of illustration specific aspects in which the disclosure may be practiced. In this regard, directional terminology, such as “top”, “bottom”, “front”, “back”, etc. may be used with reference to the orientation of the figures being described. Since components of described devices may be positioned in a number of different orientations, the directional terminology may be used for purposes of illustration and is in no way limiting. Other aspects may be utilized and structural or logical changes may be made without departing from the concept of the present disclosure. Hence, the following detailed description is not to be taken in a limiting sense, and the concept of the present disclosure is defined by the appended claims.

Methods and devices as described herein may include or utilize one or more semiconductor chips (or semiconductor dies). In general, a semiconductor chip may include integrated circuits, passive electronic components, active electronic components, etc. The integrated circuits may be designed as logic integrated circuits, analog integrated circuits, mixed signal integrated circuits, power integrated circuits, etc. A semiconductor chip need not be manufactured from a specific semiconductor material, such as e.g. silicon, and may contain inorganic and/or organic materials that are not semiconductors, such as e.g., insulators, plastics, metals, etc.

In particular, a semiconductor chip may be a sensor chip including a sensing structure. The sensing structure may include one or more micro-mechanical structures that may be used for sensing physical signals. During a sensing process a micro-mechanical structure may be moved with respect to other components of the semiconductor chip. A space arranged adjacent to the sensing structure may be referred to as sensor cell. For example, an air space arranged next to a membrane of a microphone may be referred to as a sensor cell. A sensor chip may particularly include a MEMS (Micro-Electro-Mechanical System) that may be integrated in the semiconductor chip. The MEMS may include one or multiple micro-mechanical structures, such as at least one of a bridge, a membrane, a cantilever, a tongue structure, etc. In one example, a MEMS may be configured to operate as a microphone or a loudspeaker. In a further example, a MEMS may be configured to operate as a sensor configured to sense a physical variable, for example pressure, temperature, humidity etc. Examples of sensors are pressure sensors, tire pressure sensors, gas sensors, humidity sensors, etc.

A sensor chip embedding one or more micro-mechanical structures may include electronic circuits configured to process electrical signals generated by the micro-mechanical structures. Alternatively or additionally, a logic (semiconductor) chip may be coupled to the sensor chip, wherein the logic chip may be configured to process electrical signals provided by the sensor chip. For example, the logic chip may include an application specific integrated circuit (ASIC).

Methods and devices as described herein may include or utilize a chip carrier over which one or more semiconductor chips may be arranged. The devices are not restricted to only include one single chip carrier, but may also include multiple carriers. The chip carrier may be manufactured of a metal, an alloy, a dielectric, a plastic, an organic material, a ceramic, combinations thereof, etc. The chip carrier may have a homogeneous structure, but may also provide internal structures like conducting paths with an electric redistribution function. The chip carrier may include at least one of a leadframe that may include one or more diepads and/or one or more leads (or pins), a single layer or multilayer laminate structure that may include one or more electrical redistribution layers and may be manufactured from at least one of a ceramic material, an organic material and a PCB material (e.g. FR-4), a circuit board, etc.

For example, a chip carrier may include a first part and a second part that are joint together. Joining the first part and the second part may include at least one of gluing, welding, soldering, sintering, embossing, rolling, etc. Here, the chip carrier may include a hole arranged in at least one of the first part and the second part, wherein the hole may form a part of a channel extending through the chip carrier. In addition, the chip carrier may include a recess arranged in at least one of the first part and the second part and forming a part of the channel as well. In one example, the first part and the second part may be formed such that a footprint of the first part may be similar to a footprint of the second part.

The devices as described herein may include a first main surface and a second main surface arranged opposite to the first main surface. At least one side surface of the device may extend from the first main surface to the second main surface. In one example, the main surfaces may be arranged substantially parallel to each other and the side surface may be arranged substantially perpendicular to the main surfaces. In a further example, an angle between a main surface and the side surface may also be smaller than ninety degrees. One of the main surfaces may particularly represent a mounting surface of the device. That is, this main surface may be configured to be mounted to e.g. a circuit board or a main board and, in this regard, may include one or more electrical contacts for providing an electrical connection between the device and the board. In particular, the surface area of the side surface may be smaller than at least one of the surface areas of the first main surface and the second main surface.

The devices as described herein may include one or more signal ports (or signal inlets). A signal port may be configured to provide access for a physical signal to reach a sensing structure of the sensor device in order to be sensed. For example, the signal port of a microphone may correspond to an opening in the device such that acoustic waves may access a movable membrane of the microphone. Sensor devices in accordance with the disclosure may have a signal port arranged at a side surface of the sensor device.

The devices as described herein may include one or more channels that may extend from a signal port of the sensor device to a sensing structure of a sensor chip included in the sensor device. A channel may be formed by applying various techniques, for example at least one of etching, coining, laminating, etc. In addition, a channel may be formed at various locations of the sensor device. In one example, a channel may be at least partly formed by a recess in a chip carrier. In a further example, a channel may be at least partly formed by a recess in a sensor chip. In a further example, a channel may be at least partly formed by a frame structure arranged at least partly around a sensing structure of a sensor chip. In a further example, a channel may be at least partly formed by a lid arranged over a sensing structure of a sensor chip. In a further example, a channel may be at least partly formed by a hole that may be arranged in at least one of a first part and a second part of a two-piece joint chip carrier as described above, wherein the hole may extend in a direction substantially perpendicular to a main surface of the chip carrier. In yet a further example a channel may be at least partly formed by a recess that may be arranged in at least one of a first part and a second part of a two-piece joint chip carrier as described above, wherein the recess may extend in a direction substantially parallel to a main surface of the chip carrier.

A cross section substantially perpendicular to the channel's direction (or course) may be of arbitrary form and may particularly depend on the technique used for manufacturing the channel. For example, the cross section may at least partly have a rounded shape, a circular shape, an elliptic shape, a linear shape, a polygonal shape and/or combinations thereof. A diameter or maximum dimension of the cross section may be smaller than 1.5 millimeter or smaller than 1.4 millimeter or smaller than 1.3 millimeter or smaller than 1.2 millimeter and so forth. The direction of the channel may be of arbitrary form and may particularly depend on the overall design and geometry of the respective sensor device. In particular, the channel may include one or more substantially linear sections.

Devices as described herein may include an encapsulation structure. According to one aspect the encapsulation structure may form a lid (or cover) providing a cavity (or space) that may house the sensor chip. In one example, the lid may be a single layer or multilayer laminate structure including at least one of a ceramic material and an organic material. Such laminate structure may further include a metal structure (or metal lid) having an (electromagnetic) shielding functionality. In further examples, the lid may be made of at least one of a metal, a glass material, silicon, a plastic material, a photoresist, etc. According to a further aspect the encapsulation structure may be made of or may include an encapsulation material that may at least partly cover one or more components of the sensor device. The encapsulation material may include at least one of a laminate, an epoxy, a filled epoxy, a glass fiber filled epoxy, an imide, a thermoplast, a thermoset polymer, a polymer blend. Various techniques may be used to encapsulate components of a device with such encapsulation material, for example at least one of compression molding, injection molding, powder molding, liquid molding, laminating, etc.

FIG. 1 schematically illustrates a cross-sectional side view of a sensor device 100 in accordance with the disclosure. The sensor device 100 is illustrated in a general manner in order to qualitatively specify aspects of the disclosure. The sensor device 100 may include further components which are not illustrated for the sake of simplicity. For example, the sensor device 100 may be extended by any of the aspects described in connection with other devices in accordance with the disclosure.

The sensor device 100 may include a chip carrier 2 and a sensor chip 4 arranged on the chip carrier 2. An encapsulation material 14 may be arranged on a main surface 3 and a side surface 5 of the sensor chip 4. In particular, the encapsulation material 14 may directly cover the main surface 3 and the side surface 5. Furthermore, a signal port 6 may be arranged at a side surface 8 of the sensor device 100, wherein the side surface 8 of the sensor device 100 extends between opposing main surfaces 7 and 9 of the sensor device 100. Here, the main surface 7 may be a mounting surface of the sensor device 100. A channel 10 may extend from the signal port 6 to a sensing structure 12 of the sensor chip 4. In the non-limiting example of FIG. 1, the channel 10 is arranged in the chip carrier 2. However, in further examples the channel 10 may also be arranged at different positions in the respective sensor device as will become apparent later on.

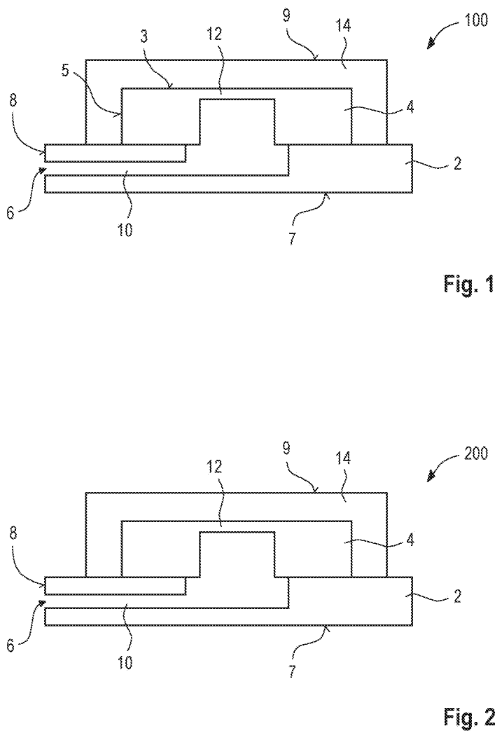

FIG. 2 schematically illustrates a cross-sectional side view of a sensor device 200 in accordance with the disclosure. The sensor device 200 is illustrated in a general manner in order to qualitatively specify aspects of the disclosure. The sensor device 200 may include further components which are not illustrated for the sake of simplicity. For example, the sensor device 200 may be extended by any of the aspects described in connection with other devices in accordance with the disclosure.

The sensor device 200 may include a chip carrier 2 and a sensor chip 4 arranged on the chip carrier 2. An encapsulation structure 14 may encapsulate the sensor chip 4. In addition, a signal port 6 may be arranged at a side surface 8 of the sensor device 200, wherein the side surface 8 of the sensor device 200 extends between opposing main surfaces 7 and 9 of the sensor device 200. Here, the main surface 7 may be a mounting surface of the sensor device 200. The signal port 6 may include a hole in the chip carrier 2. A channel 10 may extend from the hole in the chip carrier 2 to a sensing structure 12 of the sensor chip 4.

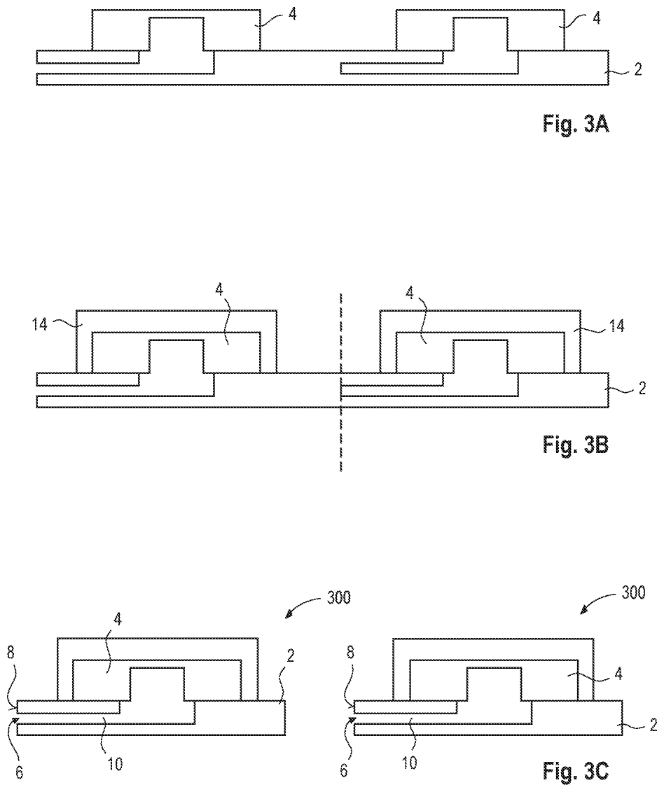

FIG. 3 includes FIGS. 3A and 3C schematically illustrating a cross-sectional side view of a method for manufacturing a sensor device 300 in accordance with the disclosure. The method of FIG. 3 is illustrated in a general manner in order to qualitatively specify aspects of the disclosure. The method may include further aspects which are not illustrated for the sake of simplicity. For example, the method may be extended by any of the aspects described in connection with other methods in accordance with the disclosure.

In FIG. 3A, multiple sensor chips 4 may be arranged over a carrier 2.

In FIG. 3B, the sensor chips 4 may be encapsulated by an encapsulation structure 14.

In FIG. 3C, the encapsulated sensor chips 4 may be separated into multiple sensor devices 300 which is also indicated by a dashed line in FIG. 3B. Here, a signal port 6 arranged at a side surface 8 of each sensor device 300 may be produced by the separation process. In the non-limiting example of FIG. 3C, the signal port 6 may have been produced by cutting through channels 10 arranged in the chip carrier 2. However, in further examples the signal port 6 may have been produced by the separation process by cutting through a channel that may be arranged at different positions in the sensor device as will become apparent later on.

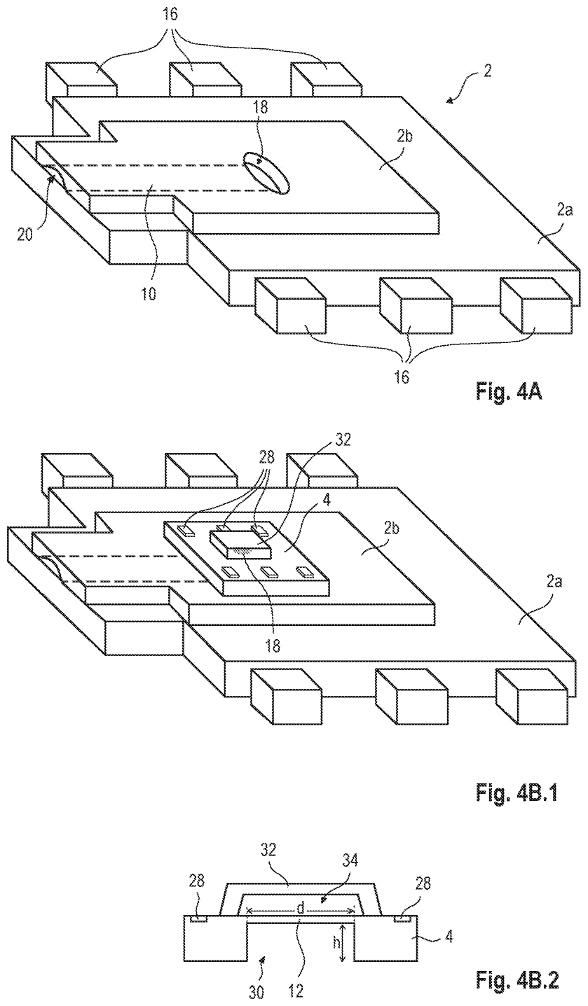

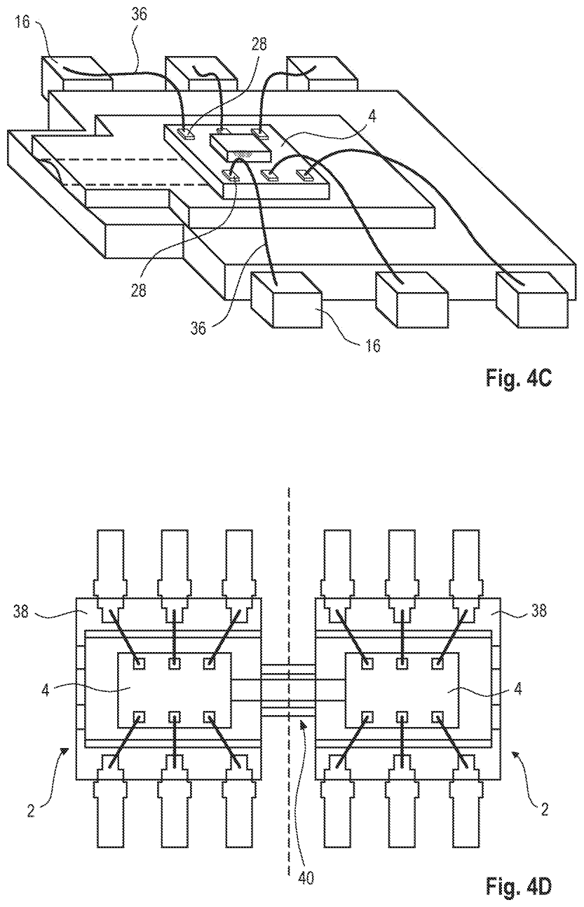

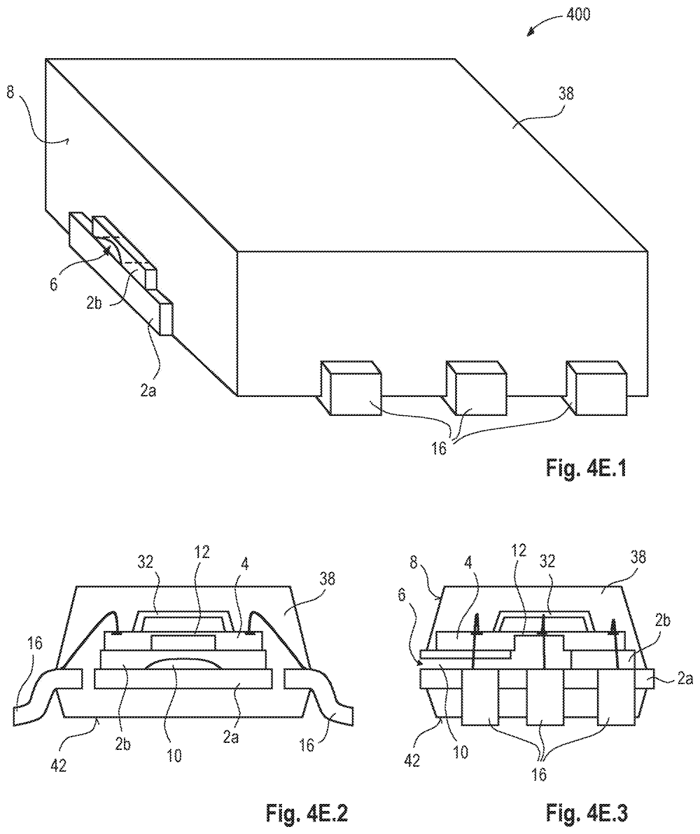

FIG. 4 includes FIGS. 4A to 4E schematically illustrating a cross-sectional side view of a method for manufacturing a sensor device 400 in accordance with the disclosure. The manufactured sensor device 400 may be seen as a more detailed implementation of the sensor devices 100 and 200 of FIGS. 1 and 2. In addition, the illustrated method may be seen as a more detailed implementation of the method of FIG. 3 such that details of the method described below may be likewise applied to the method of FIG. 3.

In FIG. 4A, a chip carrier 2 may be provided. In the example of FIG. 4A, the chip carrier 2 may be a leadframe including a first part 2a, a second part 2b and multiple leads (or pins) 16. Note that the illustrated number of six leads 16 is exemplary and may differ in further examples. The leadframe 2 may e.g. be fabricated from metals and/or metal alloys, in particular at least one of copper, copper alloys, nickel, iron nickel, aluminum, aluminum alloys, steel, stainless steel, and other appropriate materials. The leadframe 2 may be plated with an electrically conductive material, for example at least one of copper, silver, palladium, gold, nickel, iron nickel, nickel phosphorus, etc. The leadframe 2 may then be referred to as “pre-plated leadframe”.

FIG. 4A only shows a single chip carrier 2. However, the described method may be applied in parallel to a plurality of chip carriers 2 which are not illustrated for the sake of simplicity. In this case, the acts of the described method may be simultaneously performed on each respective arrangement. For example, a leadframe 2 may be one of multiple leadframes that may be mechanically connected and form a leadframe strip. The plurality of leadframes may then be separated from each other later on.

For example, the first part 2a and the leads 16 may correspond to a diepad and leads of a conventional leadframe. The second part 2b may correspond to an additional component arranged over the mounting surface of the diepad. The first part 2a and the second part 2b of the chip carrier 2 may be joint together, wherein joining the two pieces may include at least one of gluing, welding, soldering, sintering, embossing, rolling, etc. In the example of FIG. 4A, the second part 2b may include a hole 18 that may extend in a direction substantially perpendicular to the top and bottom main surfaces of the second part 2b. Furthermore, the second part 2b may include a recess 20 that may extend in a direction substantially parallel to the top and bottom main surfaces of the second part 2b. The hole 18 and the recess 20 may form a channel 10 extending through the chip carrier 2 indicated by a dashed line. The channel 10 may thus include a first substantially linear section formed by the hole 18 and extending in a direction substantially perpendicular to the main surfaces of the second part 2b and a second substantially linear section formed by the recess 20 and extending in a direction substantially parallel to the main surfaces of the second part 2b. The channel 10 may connect a first opening arranged at a side surface of the second part 2b and a second opening formed by the hole 18 arranged at the top surface of the second part 2b.

FIG. 4B includes FIGS. 4B.1 and 4B.2 illustrating a perspective view and a cross-sectional side view of the described arrangement, respectively. A sensor chip 4 including a sensing structure 12 may be arranged over the second part 2b of the chip carrier 2. In one example, the sensor chip 4 may be a microphone or a pressure sensor, and the sensing structure 12 may be a membrane. Such membrane may e.g. have a substantially circular form when viewed in a direction perpendicular to the top surface of the sensing structure 12. A diameter d of the membrane may lie in a range from about 0.6 mm to about 1.2 mm, more particular from about 0.7 mm to about 1.1 mm, and even more particular from about 0.8 mm to about 1.0 mm. An exemplary value for the diameter d may be about 0.9 mm. In a further example, the sensor chip 4 may be a gas sensor for an adsorption of gas molecules.

The sensor chip 4 may include electrical contacts 28 that may be arranged over a top surface of the sensor chip 4. Note that the illustrated number of six electrical contacts 28 and their position on the top main surface of the sensor chip 4 is exemplary and may differ in further examples. The sensor chip 4 may be attached to the second part 2b such that the sensing structure 12 may face the hole 18. Accordingly, a first space 30 may be located underneath the sensing structure 12. The first space 30 may be referred to as sensor cell. For the example of the sensor chip 4 being a microphone, the first space 30 may be a front volume of the microphone. A height h of the first space 30 may lie in a range from about 0.1 mm to about 0.7 mm, more particular from about 0.2 mm to about 0.6 mm, and even more particular from about 0.3 mm to about 0.5 mm. An exemplary value for the height h may be about 0.4 mm.

The sensor chip 4 may include electronic circuits that may be configured to process electrical signals generated by the sensing structure 12. Alternatively or additionally, a logic chip (not illustrated) may be arranged over the first part 2a or over the second part 2b. Such logic chip may be coupled to the sensor chip 4 and may be configured to process electrical signals provided by the sensor chip 4 and based on a movement of the sensing structure 12. For example, the logic chip may include an application specific integrated circuit (ASIC).

A lid (or cap) 32 may be arranged over the sensor chip 4, in particular over the sensing structure 12. The lid 32 may be optional and may be required for certain applications, such as e.g. a pressure sensor, in order to enable a movement of the sensing structure 12. The lid 32 and the sensing structure 12 may form a second space 34 arranged in between. Here, the edge of the lid 32 and the top surface of the sensor chip 4 may particularly be flush with each other such that the second space 34 is not open at the edge of the lid 32. For the example of the sensor chip 4 being a microphone, the second space 34 may correspond to a back volume of the microphone. The lid 32 may e.g. be made of at least one of a ceramic material, an organic material, a metal, a glass material, silicon, a plastic material, a photoresist, etc.

In FIG. 4C, the electrical contacts 28 of the sensor chip 4 may be electrically connected to the leads 16. In the example of FIG. 4C, the electrical connections may be established via wirebonds 36. In a further example, the sensor chip 4 may be of flip chip type, wherein the electrical connections may be provided by gluing and/or soldering.

As previously mentioned, for the sake of simplicity, FIGS. 4A to 4C only illustrated a single leadframe (or chip carrier) 2 that may be part of a leadframe strip. FIG. 4D illustrates a top view of such leadframe strip, wherein each of the included leadframes 2 may be similar to the leadframe 2 described in connection with foregoing figures.

In FIG. 4D, the components of each leadframe arrangement may be encapsulated by an encapsulation structure. In the example of FIG. 4D, an encapsulation material 38 may be deposited over the components, wherein the encapsulation material 38 may include at least one of a laminate, an epoxy, a filled epoxy, a glass fiber filled epoxy, an imide, a thermoplast, a thermoset polymer, a polymer blend, etc. The encapsulation material 38 may be deposited by using a molding technique. Here, a molding material may at least partly cover at least one of the sensor chip 4, the wire bonds 36, the top main surfaces of the first part 2a and the second part 2b, the leads 16. The encapsulation material 38 may be applied such that the opening of the channel 10 arranged at the side surface of the second part 2b remains uncovered by the encapsulation material 38. For this purpose, the opening at the side surface of the second part 2b may be covered or sealed by a mold tool during the molding process. In addition, a mechanical connection 40 between the leadframes 2 may remain uncovered by the encapsulation material 38 which may simplify a process of singulating the leadframes 2 from each other later on.

In FIG. 4D, the leadframe arrangements may be separated from each other into multiple sensor devices, wherein the separation is indicated by a dashed line. The separation process may include at least one of sawing, cutting, applying a laser beam, milling, etching.

FIG. 4E includes FIGS. 4E.1, 4E.2 and 4E.3. FIG. 4E.1 illustrates a perspective view of an exemplary separated sensor device 400. In addition, FIGS. 4E.2 and 4E.3 illustrate cross-sectional views of further exemplary separated sensor devices. In particular, FIG. 4E.2 illustrates a cross-sectional view perpendicular to the direction of the channel 10, and FIG. 4E.3 illustrates a cross-sectional view parallel to the direction of the channel 10. Note that the leads 16 of the device of FIG. 4E.2 is of gullwing type and may differ from the leads 16 shown in FIG. 4E.1.

The encapsulation material 38 may at least partly cover the first part 2a and the second part 2b of the chip carrier 2, the sensor chip 4, the lid 32 and the leads 16. The end parts of the leads 16 may at least partly protrude out of the encapsulation material 38. The sensor device 400 may be mounted on an external component, such as e.g. a board (not illustrated), wherein the uncovered end parts of the leads 16 may provide an electrical connection between the board and the sensor chip 4 and/or a logic chip of the sensor device (not illustrated).

The sensor device 400 may include a signal port 6 arranged at a side surface 8 of the sensor device 400. In the example of the perspective view, the side surface 8 of the sensor device 400 may be arranged substantially perpendicular to the mounting surface 42 of the sensor device 400. Note that the angle between the side surface 8 and the mounting surface 42 may particularly depend on the form of a used mold tool. The two cross-sectional views on the bottom left and bottom right illustrate examples, wherein an inclination of the side surface may differ from the perspective view. Here, an angle between the side surface 8 and the mounting surface 42 may also be smaller (or greater) than ninety degrees. Note further that the surface area of the side surface 8 may particularly be smaller than the surface area of each of the top and bottom main surfaces of the sensor device 400. The channel 10 may extend from the signal port 6 at the side surface 8 to the sensing structure 12 of the sensor chip 4. Due to the shape of a mold tool used during the encapsulation process, the ends of the first part 2a and the second part 2b may at least partly protrude out of the encapsulation material 38.

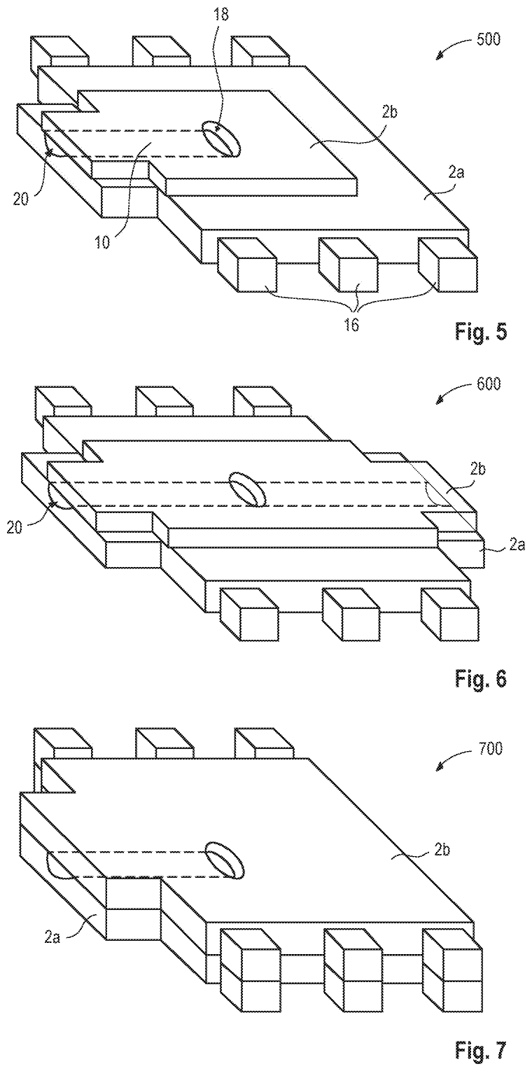

FIG. 5 schematically illustrates a perspective view of a chip carrier 500 which may be similar to the chip carrier 2 of FIG. 4A. Comments made in connection with FIG. 4A may thus also hold true for FIG. 5. Note that the chip carrier 500 of FIG. 5 may also be used in the method of FIG. 4. In this regard, the chip carrier 500 may particularly replace the chip carrier 2 in FIG. 4A. The chip carrier 500 may be a leadframe including a first part 2a, a second part 2b and multiple leads (or pins) 16. In the example of FIG. 5, the second part 2b may include a hole 18 similar to the hole 18 in FIG. 4A. In addition, the first part 2a may include a recess 20 that may extend in a direction substantially parallel to the main surfaces of the first part 2a. The hole 18 and the recess 20 may form a channel 10 indicated by a dashed line. The chip carrier 500 of FIG. 5 may differ from the chip carrier 2 of FIG. 4A in that the recess 20 is now arranged in the first part 2a. A sensor device manufactured based on the method of FIG. 4 and using the chip carrier 500 of FIG. 5 may also include a signal port (or signal inlet) arranged at a side surface of the manufactured sensor device.

FIG. 6 schematically illustrates a perspective view of a chip carrier 600 which may be similar to the chip carrier 2 of FIG. 4A. Comments made in connection with FIG. 4A may thus also hold true for FIG. 6. Note that the chip carrier 600 of FIG. 6 may also be used in the method of FIG. 4. In this regard, the chip carrier 600 may particularly replace the chip carrier 2 illustrated in FIG. 4A. In the example of FIG. 6, the recess 20 may be arranged in the first part 2a and may extend from a first opening arranged at the left side surface of the first part 2a to a second opening arranged at the opposing right side surface of the first part 2a. A sensor device manufactured based on the method of FIG. 4 and using the chip carrier 600 of FIG. 6 may thus include two signal ports (or signal inlets) that may be arranged at opposing side surfaces of the manufactured sensor device. For example, such sensor device may be a gas sensor, wherein the (continuous) channel 10 may be configured to enable a gas flow.

FIG. 7 schematically illustrates a perspective view of a chip carrier 700 which may be similar to the chip carrier 2 of FIG. 4A. Comments made in connection with FIG. 4A may thus also hold true for FIG. 7. Note that the chip carrier 700 may also be used in the method of FIG. 4. In this regard, the chip carrier 700 may particularly replace the chip carrier 2 in FIG. 4A. The chip carrier of FIG. 7 may differ from the chip carrier 2 of FIG. 4A in that a footprint of the first part 2a may be (substantially) similar to a footprint of the second part 2b when viewed in a direction perpendicular to the main surface of the chip carrier 2. For example, the first part 2a and the second part 2b may correspond to completely laminated chip carriers having a same geometry. A sensor device manufactured based on the method of FIG. 4 and using the chip carrier 700 of FIG. 7 may include a signal port (or signal inlet) arranged at a side surface of the manufactured sensor device.

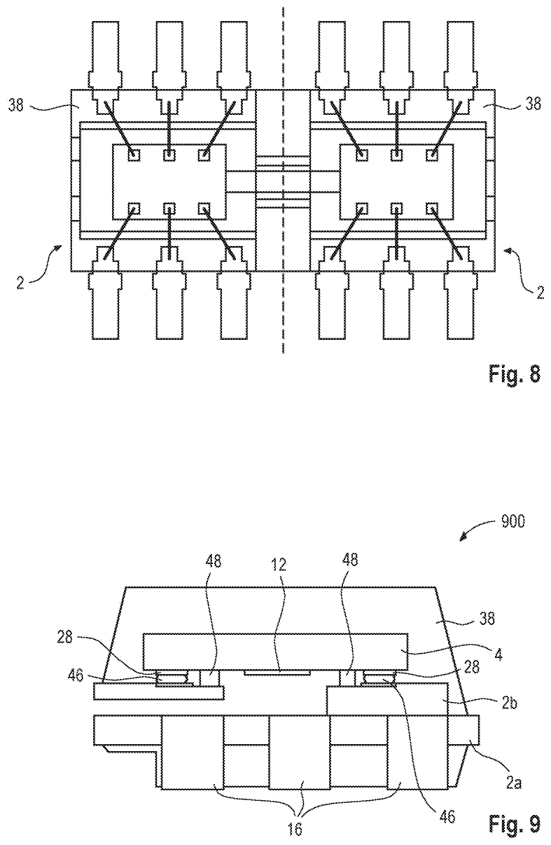

FIG. 8 schematically illustrates a top view of an act of encapsulating multiple sensor chips arranged over chip carriers. The illustrated act may be used in the method of FIG. 4 and, in this regard, may replace the act of FIG. 4D. As previously described in connection with FIG. 4D, multiple components arranged over the leadframes 2 of a leadframe strip may be encapsulated by an encapsulation structure, such as e.g. a molding material 38. In the example of FIG. 4D, openings at the side surfaces of the chip carriers were covered or sealed by a mold tool during the molding process. In contrast to this, the molding material 38 in FIG. 8 may (continuously) cover multiple leadframes (array molding). The signal ports at the side surfaces of the sensor devices to be manufactured may then be produced (or opened) by the separation process indicated by a dashed line. In particular, the signal ports may result from separating the sensor devices through the channels arranged in the respective chip carriers. In the foregoing example of FIG. 4E, the ends of the first part 2a and the second part 2b protruded out of the encapsulation material 38. In contrast to this, applying the act of FIG. 8 may result in that the ends of the first part 2a and the second part 2b and the side surface of the encapsulation material 38 may be arranged in a common plane after the separation process.

FIG. 9 schematically illustrates a cross-sectional side view of a sensor device 900 in accordance with the disclosure. The sensor device 900 may be at least partly manufactured based on the method of FIG. 4. Comments made in connection with FIG. 4 may thus also hold true for FIG. 9. In the foregoing example of FIG. 4, the electrical contacts 28 of the sensor chip 4 were arranged on its top main surface. Further, an electrical connection between the electrical contacts 28 and the leads 16 was established via wire bonds 36. In contrast to this, the sensor chip 4 of FIG. 9 may be of flip chip type including electrical contacts 28 arranged over a main surface of the sensor chip 4 facing the chip carrier 2. In such case, the sensing structure 12 may be particularly arranged on the bottom main surface of the sensor flip chip 4. An electrical connection between the sensor chip 4 and the leads 16 of the chip carrier 2 may be at least partly provided via solder balls (or solder bumps) 46. Note that due to the chosen perspective of FIG. 9 such electrical connection may be not completely illustrated. The sensor device 900 may include further electrically conductive parts that may contribute to such electrical connection, but may be not visible in FIG. 9. The sensor device 900 may optionally include a sealing structure 48 that may be arranged at least partly around the sensing structure 12. The sealing structure 48 may be configured to keep an access to the sensing structure 12 free from the encapsulation material 38 during the encapsulation process.

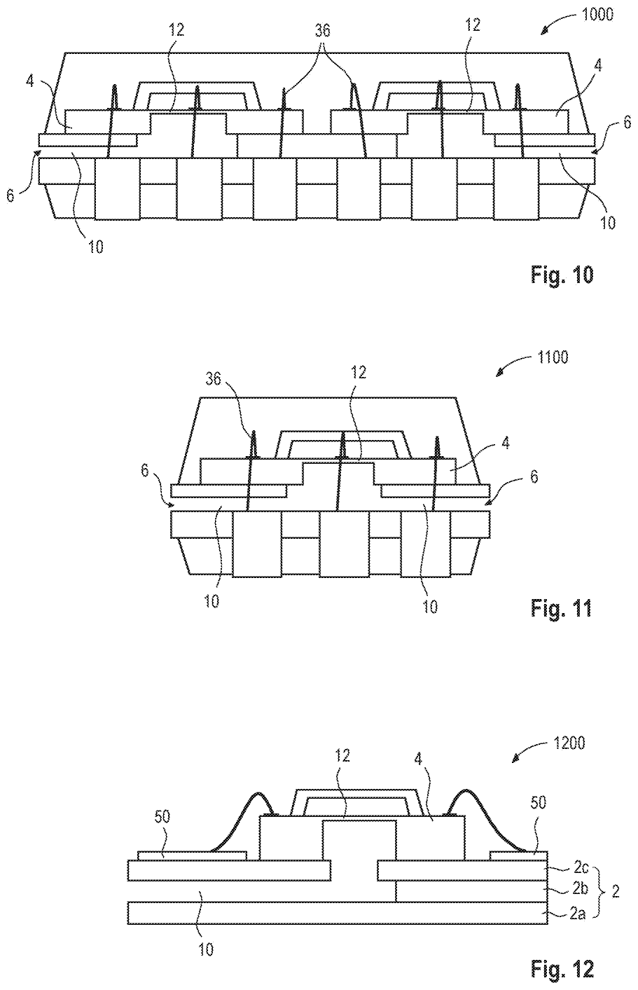

FIG. 10 schematically illustrates a cross-sectional side view of a sensor device 1000 in accordance with the disclosure. The sensor device 1000 may be at least partly manufactured based on the method of FIG. 4. Comments made in connection with FIG. 4 may thus also hold true for FIG. 10. In contrast to foregoing examples, the sensor device 1000 may include two sensor chips 4 including a sensing structure 12, respectively. Each of the sensing structures 12 may be in connection to a signal port 6 arranged at a side surface of the sensor device 1000 via a channel 10. For example, the sensor chips 4 may be pressure sensors of similar (or different) type such that the sensor device 1000 may be configured to operate as a differential pressure sensor. In the example of FIG. 10, the sensor device 1000 may include two signal ports 6, two channels 10 and two sensor chips 4. Sensor devices of further examples may include an arbitrary number of additional signal ports, channels and/or sensor chips.

FIG. 11 schematically illustrates a cross-sectional side view of a sensor device 1100 in accordance with the disclosure. The sensor device 1100 may be at least partly manufactured based on the method of FIG. 4. Comments made in connection with FIG. 4 may thus also hold true for FIG. 11. The sensor device 1100 may include a sensor chip 4 with a sensing structure 12 that may be connected to two signal ports 6 arranged on two side surfaces of the sensor device 1100 via one channel 10. That is, the sensing structure 12 may be accessible for physical signals to be measured via two different signal ports 6 and the same channel 10. In one example, the sensor device 1100 may configured to operate as a gas sensor, wherein the channel 10 may be configured to enable a gas flow. The sensor device 1100 may e.g. be manufactured using the chip carrier 600 of FIG. 6.

FIG. 12 schematically illustrates a cross-sectional side view of a sensor device 1200 in accordance with the disclosure. The sensor device 1200 may be at least partly manufactured based on the method of FIG. 4. Comments made in connection with FIG. 4 may thus also hold true for FIG. 12. The sensor device 1200 may include a chip carrier 2 that may be formed by a multilayer laminate structure made of at least one of a ceramic material, an organic material and a PCB material (e.g. FR-4). The laminate structure 2 may include an exemplary number of three layers 2a, 2b, 2c that may form a channel 10 arranged in chip carrier 2. A sensor chip 4 including a sensing structure 12 may be arranged over the chip carrier 2. An electrical connection between the sensor chip 4 and further components (not illustrated) may be provided via conductive structures 50 arranged over the chip carrier 2. The device 1200 may include further components which are not illustrated for the sake of simplicity. For example, the sensor chip 4 may be encapsulated by an encapsulation structure (not illustrated), such as e.g. a molding material.

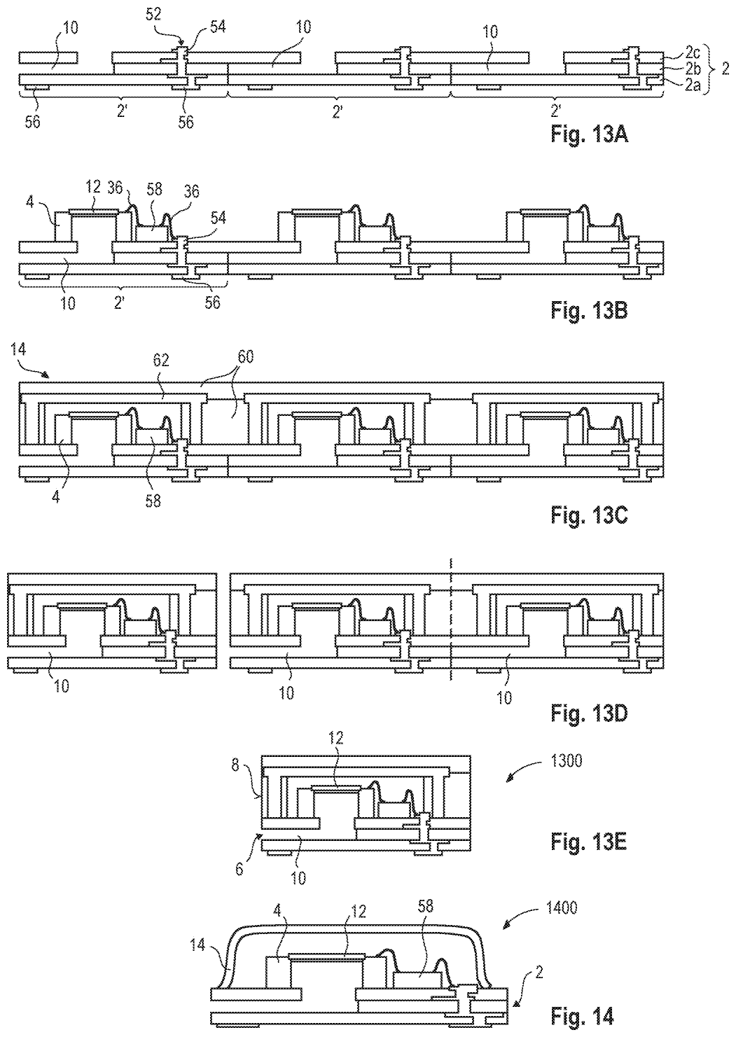

FIG. 13 includes FIGS. 13A to 13E schematically illustrating a cross-sectional side view of a method for manufacturing a sensor device 1300 in accordance with the disclosure. The manufactured sensor device 1300 may be seen as a more detailed implementation of the sensor devices 100 and 200 of FIGS. 1 and 2. In addition, the illustrated method may be seen as a more detailed implementation of the method of FIG. 3 such that details of the method described below may be likewise applied to the method of FIG. 3.

In FIG. 13A, a chip carrier 2 may be provided. The chip carrier 2 may consist of multiple substantially identical segments 2′. In the example of FIG. 13A, only three of such segments 2′ are illustrated for the sake of simplicity. In further examples, the number of segments 2′ may be different. Each of the segments 2′ may be formed by a multilayer laminate structure made of at least one of a ceramic material, an organic material and a PCB material (e.g. FR-4). The chip carrier 2 may include an exemplary number of there layers 2a, 2b, 2c that may form channels 10 in the chip carrier 2. In addition, each of the segments 2′ may include an electrical redistribution structure 52 that may extend through the chip carrier 2 and provide an electrical interconnection between one or more electrical contacts 54 arranged on the top main surface of the chip carrier 2 and one or more electrical contacts 56 arranged on the bottom main surface of the chip carrier 2. The electrical contacts 56 arranged on the bottom surface of the chip carrier 2 may be configured to provide an electrical connection between the sensor device to be manufactured and an external component, such as e.g. a board, onto which the sensor device may be mounted later on.

For example, the electrical redistribution structure 52 may be formed by multiple conductive layers that may be made of a metal. Note that due to the chosen perspective of FIG. 13A the electrical redistribution structure 52 extending through the chip carrier 2 may not be completely illustrated. For example, the left electrical contact 56 on the bottom main surface of the chip carrier 2 is illustrated to be isolated, but actually may be connected to further electrically conductive structures, although not explicitly visible in the example of FIG. 13A.

In FIG. 13B, a sensor chip 4 including a sensing structure 12 may be arranged over each segment 2′ of the chip carrier 2, wherein the sensing structure 12 may be located over an opening of the channel 10. In addition, a logic chip 58 configured to process electrical signals provided by the sensor chip 4 may be arranged over each segment 2′. The sensor chip 4 may be electrically connected to the logic chip 58 via a wire bond 36. Similarly, the logic chip 58 may be electrically connected to the electrical contact 54 arranged on the top surface of the chip carrier 2 via a wire bond 36. That is, the logic chip 58 be electrically accessible at the electrical contact 56 arranged on the bottom surface of the chip carrier 2 via the electrical redistribution structure 52.

In FIG. 13C, the sensor chip 4 and the logic chip 58 may be encapsulated by an encapsulation structure 14. The encapsulation structure 14 may include a laminate structure including one or multiple layers 60 that may be made of a ceramic material and/or an organic material. In addition, the encapsulation structure 14 may include a metal structure 62 that may be configured to provide an (electromagnetic) shielding functionality. In this regard, the metal structure 62 may be connected to a grounding contact. The encapsulation structure 14 may form a cavity or space that may house the sensor chip 4 and the logic chip 58. The logic chip 58 and electrical contacts arranged on the top surface of the logic chip may be additionally protected by a polymer material (not illustrated), such as e.g. a glob-top material, in order to avoid a corrosion of the electrical contacts.

In FIG. 13D, the segments 2′ of the chip carrier 2 may be separated into multiple sensor devices, wherein the separation is indicated by a dashed line. The separation process may include at least one of sawing, cutting, applying a laser beam, milling, etching. The separation process is realized such that the channels 10 are opened at the side surfaces of the separated sensor devices 1300.

FIG. 13E illustrates one of the separated sensor devices 1300. Due to separating the sensor devices 1300 through the channel 10, a signal port 6 arranged at a side surface 8 of the sensor device 1300 may have been produced. The side surface 8 may be arranged substantially perpendicular to the mounting surface of the sensor device 1300 and/or substantially perpendicular to the sensing structure 12. In one example, the sensor device 1300 may be a microphone and the signal port 6 may be an acoustic port.

FIG. 14 schematically illustrates a cross-sectional side view of a sensor device 1400 in accordance with the disclosure. The sensor device 1400 may be at least partly manufactured based on the method of FIG. 13. Comments made in connection with FIG. 13 may thus also hold true for FIG. 14. The sensor device 1400 of FIG. 14 may differ from the sensor device 1300 of FIG. 13E with respect to the included encapsulation structure. In the example of FIG. 14, the encapsulation structure may be a metal lid 14 which may form a cavity or space housing the sensor chip 4 and the logic chip 58. The metal lid 14 may be connected to a grounding contact arranged over the top surface of the chip carrier 2 in order to provide an (electromagnetic) shielding functionality.

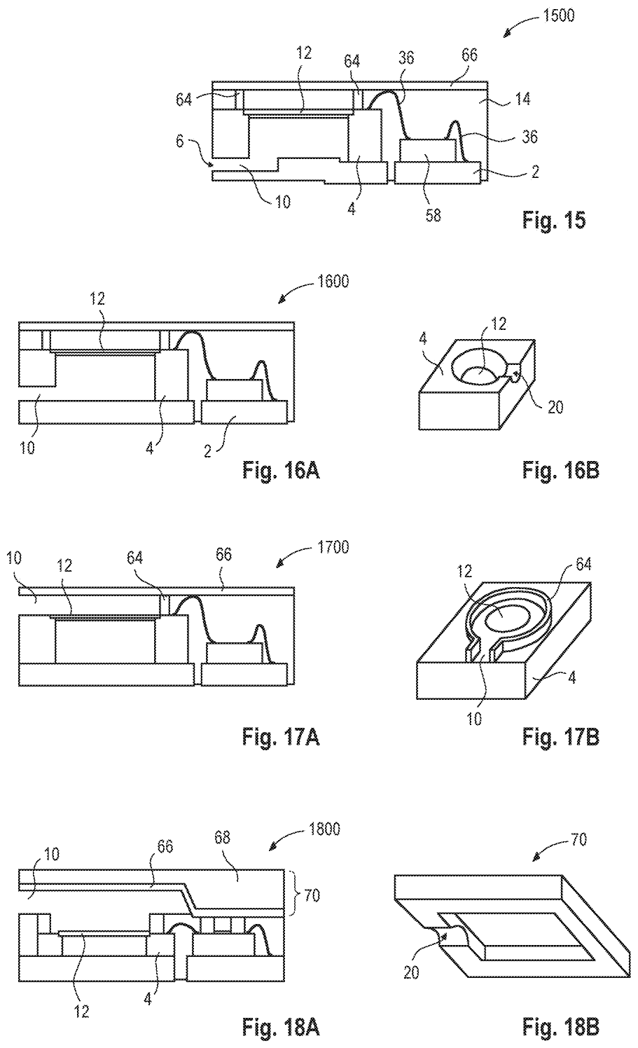

FIG. 15 schematically illustrates a cross-sectional side view of a sensor device 1500 in accordance with the disclosure. The sensor device 1500 may be at least partly manufactured based on the method of FIG. 13. Comments made in connection with FIG. 13 may thus also hold true for FIG. 15. The sensor device 1500 may include a chip carrier 2 such as e.g. a leadframe. A sensor chip 4 including a sensing structure 12 and a logic chip 58 may be arranged over the chip carrier 2. The sensor chip 4 may be electrically connected to the logic chip 58 via one or more wire bonds 36. Similarly, the logic chip 58 may be electrically connected to the chip carrier 2 or electrical contacts arranged thereon via one or more wire bonds 36. A channel 10 may be at least partly formed by a recess in the chip carrier 2, wherein the cross-sectional side view of FIG. 15 may be parallel to the direction of the channel 10. In one example, the top part of the channel 10 may thus be delimited by material of the sensor chip 4 while the bottom part and side parts of the channel 10 may be delimited by material of the chip carrier 2. For example, the recess in the chip carrier may be formed by etching, coining, etc.

The sensor device 1500 may further include a frame structure (or spacer structure) 64 that may be arranged over the sensor chip 4. In particular, the frame structure 64 may at least partly surround the sensing structure 12. When viewed in a direction perpendicular to the top surface of the sensing structure 12, the frame structure 64 may e.g. have a circular shape. A lid 66 may be arranged over the frame structure 64. For example, the lid 66 may be made of a metal and may provide an (electromagnetic) shielding functionality as described in foregoing paragraphs. The frame structure 64 and the lid 66 may form a cavity or space arranged over the sensing structure 12. For the case of the sensor device 1500 being a microphone, the space over the sensing structure 12 may be a back volume of the microphone. The sensor device 1500 may further include an encapsulation material 14 which may at least partly cover one or more of the above described components of the sensor device 1500. The encapsulation material 14 may e.g. include at least one of a laminate, an epoxy, a filled epoxy, a glass fiber filled epoxy, an imide, a thermoplast, a thermoset polymer, a polymer blend, etc.

FIG. 16 includes FIGS. 16A and 16B. FIG. 16A schematically illustrates a cross-sectional side view of a sensor device 1600 in accordance with the disclosure. The sensor device 1600 may be at least partly manufactured based on the method of FIG. 13 and may be at least partly similar to the sensor device 1500 of FIG. 15. Comments made in connection with FIGS. 13 and 15 may thus also hold true for FIG. 16. In contrast to FIG. 15, the channel 10 of the sensor device 1600 may be at least partly formed by a recess in the sensor chip 4, wherein the cross-sectional side view of FIG. 16A may be parallel to the direction of the channel 10. In one example, the top part and side parts of the channel 10 may thus be delimited by material of the sensor chip 4 while the bottom part of the channel 10 may be delimited by material of the chip carrier 2. For example, the recess may be formed by etching, coining, etc.

FIG. 16B schematically illustrates a perspective bottom view of a sensor chip 4 that may be included in the sensor device 1600. The sensor chip 4 may include a recess 20 that may form the channel 10 of the sensor device 1600. In the example of FIG. 16B, a cross section of the recess 20 may at least partly have a rounded shape. In further examples, the cross section may also have an elliptic shape, a linear shape, a polygonal shape and/or combinations thereof.

FIG. 17 includes FIGS. 17A and 17B. FIG. 17A schematically illustrates a cross-sectional side view of a sensor device 1700 in accordance with the disclosure. The sensor device 1700 may be at least partly manufactured based on the method of FIG. 13. Comments made in connection with FIG. 13 may thus also hold true for FIG. 17. In contrast to FIG. 15 or 16, the channel 10 of the sensor device 1700 may be at least partly formed by a frame structure 64 arranged over the sensing structure 12. In particular, the frame structure 64 may be arranged at least partly around the sensing structure 12. The cross-sectional side view of FIG. 17A is parallel to the direction of the channel 10. In one example, the top part of the channel 10 may thus be delimited by material of the lid 66, the side parts of the channel 10 may be delimited by material of the frame structure 64, and the bottom part of the channel 10 may be delimited by material of the sensor chip 4.

FIG. 17B schematically illustrates a perspective top view of the sensor chip 4, the sensing structure 12 and the frame structure 64 as they may be included in the sensor device 1700. In the example of FIG. 17B, the frame structure 64 may at least partly have a circular or rounded shape. In further examples, the frame structure 64 may also have an elliptic shape, a rectangular shape, a polygonal shape and/or combinations thereof.

FIG. 18 includes FIGS. 18A and 18B. FIG. 18A schematically illustrates a cross-sectional side view of a sensor device 1800 in accordance with the disclosure. The sensor device 1800 may be at least partly manufactured based on the method of FIG. 13. Comments made in connection with FIG. 13 may thus also hold true for FIG. 18. The sensor device 1800 may include a lid structure 70 arranged over the sensing structure 12. The lid structure 70 may include a metal lid 66 and a material 68 arranged thereon. For example, the material 68 may be similar to the encapsulation material 14 in FIG. 15. In contrast to foregoing figures, the channel 10 of the sensor device 1800 may be at least partly formed by the lid structure 70, in particular by a recess in the lid structure 70. The cross-sectional side view of FIG. 18A is parallel to the direction of the channel 10.

FIG. 18B schematically illustrates a perspective bottom view of a lid structure 70 similar to the lid structure 70 of the sensor device 1800. The lid structure 70 may include a recess 20 that may result in a channel 10 when used in the fabrication of a sensor device.

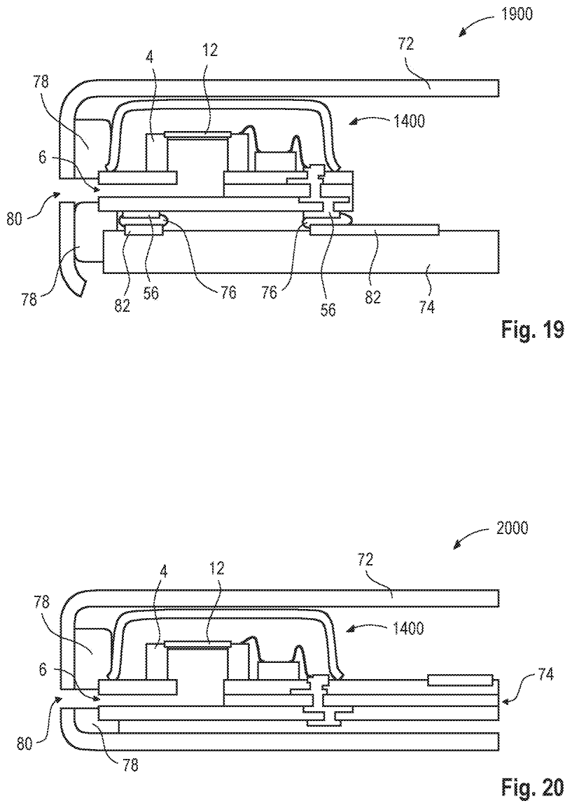

FIG. 19 schematically illustrates a cross-sectional side view of an electronic device 1900 which, in one example, may be a smartphone. The electronic device 1900 may include a housing 72 with an opening 80 arranged on a side surface of the housing 72. A main board 74 may be arranged in the housing 72, wherein one or more electrical contacts 82 may be arranged on the top surface of the main board 74. The electronic device 1900 may further include a sensor device 1400 which may be similar to the sensor device of FIG. 14. Note that the sensor device 1400 of FIG. 19 may also be replaced by any other similar sensor device in accordance with the disclosure as described in connection with foregoing figures. A sealing structure 78 may be arranged between the sensor device 1400 and the opening 80 of the housing 72. For example, the sealing structure 78 may have the form of a ring, wherein FIG. 19 illustrates a cross-section through the ring.

The sensor device 1400 may be mounted on the main board 74, wherein an electrical connection between electrical contacts 56 arranged on the bottom main surface of the sensor device 1400 and the electrical contacts 82 of the main board 74 may be provided. In this connection, a solder material 76 may be arranged between the electrical contacts 56 and 82. The sealing structure 78 may provide a mechanical connection between the housing 72 and the sensor device 1400. Here, the sensor device 1400 may be arranged such that the signal port 6 of the sensor device 1400 may face the opening 80. The opening 80 of the housing 72, the inner walls of the sealing structure 78 and the channel 10 of the sensor device 1400 may form a combined channel connecting the environment with the sensing structure 12 of the sensor chip 4. Hence, the opening 80 of the housing 72 may represent a sidewall acoustic port of the electronic device 1900, e.g. for a smartphone. For example, acoustic waves generated by a user talking on the smartphone may enter the opening 80 and propagate through the channel 10 to reach the sensing structure 12 of the sensor chip 4.

FIG. 20 schematically illustrates a cross-sectional side view of an electronic device 2000 which, in one example, may be a smartphone. The electronic device 2000 may be similar to the electronic device 1900 of FIG. 19 such that comments made in connection with FIG. 19 may also hold true for FIG. 20. In the example of FIG. 20, the electronic device 2000 may include a main board 74 which may be formed by a multilayer laminate structure made of at least one of a ceramic material, an organic material and a PCB material (e.g. FR-4). For example, the main board 74 may be similar to the chip carrier 2 in FIG. 13A. A part of the main board 74 may form the chip carrier 2 of the sensor device 1400 included in the electronic device 2000. Thus, the electronic device 2000 may not require an additional main board as shown in the example of FIG. 19.

Devices and methods in accordance with the disclosure may provide the following technical effects which are neither exclusive nor limiting.

The aspects described herein may provide an increased flexibility for package layouts in which the arrangement of signal ports is not limited to a location at the bottom or top of the sensor device.

The aspects described herein may provide sensor devices with microchannels for e.g. gas/liquids flow purposes. In this regard, even complicated channel structures, various signal inlets and a redistribution of the signal inlet to some other location at the sidewall of the sensor device may be provided.

The aspects described herein may provide a reduced height of sensor devices and of applications including such sensor devices, such as e.g. smartphones, etc.

The fabrication of devices described herein does not necessarily require cost-intensive premold packages or complex mold processes which may result in reduced manufacturing costs.

The aspects described herein are not limited to a specific application, but may be applied to a variety of sensor applications such as e.g. microphones, pressure sensors, gas sensors, etc.

As employed in this specification, the terms “connected”, “coupled”, “electrically connected” and/or “electrically coupled” may not necessarily mean that elements must be directly connected or coupled together. Intervening elements may be provided between the “connected”, “coupled”, “electrically connected” or “electrically coupled” elements.

Further, the word “over” used with regard to e.g. a material layer formed or located “over” a surface of an object may be used herein to mean that the material layer may be located (e.g. formed, deposited, etc.) “directly on”, e.g. in direct contact with, the implied surface. The word “over” used with regard to e.g. a material layer formed or located “over” a surface may also be used herein to mean that the material layer may be located (e.g. formed, deposited, etc.) “indirectly on” the implied surface with e.g. one or more additional layers being arranged between the implied surface and the material layer.

Furthermore, to the extent that the terms “having”, “containing”, “including”, “with” or variants thereof are used in either the detailed description or the claims, such terms are intended to be inclusive in a manner similar to the term “comprising”. That is, as used herein, the terms “having”, “containing”, “including”, “with”, “comprising” and the like are open-ended terms that indicate the presence of stated elements or features, but do not preclude additional elements or features. The articles “a”, “an” and “the” are intended to include the plural as well as the singular, unless the context clearly indicates otherwise.

Moreover, the word “exemplary” is used herein to mean serving as an example, instance, or illustration. Any aspect or design described herein as “exemplary” is not necessarily to be construed as advantageous over other aspects or designs. Rather, use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims may generally be construed to mean “one or more” unless specified otherwise or clear from context to be directed to a singular form. Also, at least one of A and B or the like generally means A or B or both A and B.

Devices and methods for manufacturing devices are described herein. Comments made in connection with a described device may thus also hold true for a corresponding method and vice versa. For example, if a specific component of a device is described, a corresponding method for manufacturing the device may include an act of providing the component in a suitable manner, even if such act is not explicitly described or illustrated in the figures. In addition, the features of the various exemplary aspects described herein may be combined with each other, unless specifically noted otherwise.

Although the disclosure has been shown and described with respect to one or more implementations, equivalent alterations and modifications will occur to others skilled in the art based at least in part upon a reading and understanding of this specification and the annexed drawings. The disclosure includes all such modifications and alterations and is limited only by the concept of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the disclosure. In addition, while a particular feature of the disclosure may have been disclosed with respect to only one of several implementations, such feature may be combined with one or more other features of the other implementations as may be desired and advantageous for any given or particular application.

1. A sensor device, comprising:
a leadframe;
a sensor chip arranged on the leadframe;
an encapsulation material arranged on a main surface and a side surface of the sensor chip;
a signal port arranged at a side surface of the sensor device, wherein the side surface of the sensor device extends between opposing main surfaces of the sensor device, wherein one of the main surfaces is a mounting surface of the sensor device; and
a channel extending from the signal port through the leadframe to a sensing structure of the sensor chip.

2. The sensor device of claim 1, wherein the encapsulation material comprises at least one of an epoxy, a filled epoxy, a glass fiber filled epoxy, an imide, a thermoplast, a thermoset polymer, a polymer blend.

3. The sensor device of claim 1, wherein the channel is at least partly formed by a recess in the leadframe.

4. The sensor device of claim 1, wherein the channel is at least partly formed by a recess in the sensor chip.

5. The sensor device of claim 1, wherein the leadframe comprises a first part and a second part joined together.

6. The sensor device of claim 5, wherein the channel is at least partly formed by a hole comprised in at least one of the first part and the second part, wherein the hole extends in a direction substantially perpendicular to a main surface of the leadframe.

7. The sensor device of claim 5, wherein the channel is at least partly formed by a recess comprised in at least one of the first part and the second part, wherein the recess extends in a direction substantially parallel to a main surface of the leadframe.

8. The sensor device of claim 5, wherein a footprint of the first part is similar to a footprint of the second part.

9. The sensor device of claim 1, further comprising:
a second signal port arranged at a side surface of the sensor device; and
a second channel extending from the second signal port to the sensing structure of the sensor chip.

10. The sensor device of claim 1, further comprising:
a second sensor chip;
a second signal port arranged at a side surface of the sensor device; and
a second channel extending from the second signal port to a sensing structure of the second sensor chip.

11. A sensor device, comprising:
a chip carrier, wherein the chip carrier comprises a multi-layer laminate structure made of a ceramic material, an organic material or a printed circuit board material;
a sensor chip arranged on the chip carrier;
an encapsulation structure encapsulating the sensor chip;
a signal port arranged at a side surface of the sensor device, wherein the side surface of the sensor device extends between opposing main surfaces of the sensor device, one of the main surfaces being a mounting surface of the sensor device, wherein the signal port comprises a hole in the chip carrier; and
a channel extending from the hole in the chip carrier through the chip carrier to a sensing structure of the sensor chip.

12. The sensor device of claim 11, wherein the encapsulation structure comprises a lid providing a cavity housing the sensor chip.

13. The sensor device of claim 11, wherein the lid comprises at least one of a glass material, silicon, a plastic material, a photoresist, a single layer or multilayer laminate structure comprising at least one of a ceramic material and an organic material.

14. The sensor device of claim 11, wherein the lid comprises at least one of a metal and a metal alloy.

15. The sensor device of claim 11, wherein the encapsulation structure comprises a molding material arranged directly on a main surface and a side surface of the sensor chip.

16. The sensor device of claim 11, wherein the sensor chip is directly arranged on the chip carrier.

17. The sensor device of claim 11, wherein the sensor chip comprises a microphone and the signal port comprises an acoustic port of the microphone.

18. A method for manufacturing a sensor device, the method comprising:
arranging multiple sensor chips on a carrier;
encapsulating the sensor chips by an encapsulation structure; and
separating the encapsulated sensor chips into multiple sensor devices, wherein a signal port arranged at a side surface of each sensor device is produced by the separation process.

19. The method of claim 18, wherein the signal ports are produced by separating the encapsulated sensor chips through channels, wherein a respective channel extends from a signal port to a sensing structure of a sensor chip.

20. The method of claim 18, wherein separating the encapsulated sensor chips into multiple sensor devices comprises at least one of sawing, cutting, applying a laser beam, milling, etching.

21. The method of claim 18, further comprising:
forming the carrier by joining together a first part of the carrier and a second part of the carrier, wherein joining the first part and the second part comprises at least one of gluing, welding, soldering, sintering, embossing, rolling.
